(19) United States
(12) Patent Application Publication
(10) Pub. No.: US 2003/0053300 A1
(43) Pub. Date: Mar. 20, 2003

(54) Electric-component supplying apparatus and method

(75) Inventors: Shinsuke Suhara, Kariya-shi (JP); Yukio Ueno, Nagoya-shi (JP); Yukihiro Fukao, Toyota-shi (JP)

Correspondence Address: OLIFF & BERRIDGE, PLC, P.O. BOX 19928, ALEXANDRIA, VA, 22320, US

(73) Assignee: FUJI MACHINE MFG. CO., LTD., Chiryu-shi (JP)

(21) Appl. No.: 10/237,101

(22) Filed: Sep. 9, 2002

(30) Foreign Application Priority Data
Sep. 18, 2001 (JP) 2001-282670

(51) Int. Cl. H05K 7/02; H05K 7/06; H05K 7/08; H05K 7/10

(52) U.S. Cl. 361/760

(57) ABSTRACT

An apparatus for supplying, in an electric-component mounting system, electric components to be mounted on a circuit substrate supported by a circuit-substrate supporting device, the apparatus including a support table, and palettes each one of which is detachably attachable to the support table and holds feeders arranged in a reference direction predetermined with respect to the electric-component mounting system, each one of the feeders feeding electric components of one sort, the palettes having different dimensions in the reference direction.

### BACKGROUND OF THE INVENTION

1. Field of the Invention

The present invention relates to an electronic-component supplying apparatus as part of an electric-component mounting system and in particular to such an electronic-component supplying apparatus which includes a plurality of feeders each one of which feeds electric components (e.g., electronic components) of one sort and which supplies electric components from the feeders.

2. Discussion of Related Art

There is known an electric-component mounting system which includes a group of feeders which respectively store and feed different sorts of electric components to be mounted on a single circuit substrate, a support table which supports the feeders in an arranged manner, and a mounting head which is positioned at a component receiving position to receive an electric component from an appropriate one of the feeders that is currently positioned there and which subsequently mounts the electric component on the circuit substrate. This electric-component mounting system needs to exchange the current group of feeders supported by the support table, with a different group of feeders, that is, reset the feeders, if the current sort of circuit substrate is changed to a new sort of circuit substrate on which electric components are to be mounted. Therefore, if this feeder-resetting operation can be carried out efficiently, the component mounting operation as a whole can be carried out efficiently.

In the case where the support table is undetachably or permanently attached to a base of the electric-component mounting system, the overall operation of the mounting system must be halted during a time period in which the feeders supported by the support table are exchanged with different feeders. This leads to lowering not only the efficiency of the component-mounting operation of the mounting system, but the rate of operation of the expensive mounting system.

### SUMMARY OF THE INVENTION

It is therefore an object of the present invention to solve at least one of the above-identified problems and thereby improve efficiency of an electric-component mounting operation of an electric-component mounting system. This object may be achieved according to any one of the following modes of the present invention in the form of an electric-component supplying apparatus and an electric-component supplying method, each of which is numbered like the appended claims and may depend from the other mode or modes, where appropriate, to indicate and clarify possible combinations of technical features. It is, however, to be understood that the present invention is not limited to the technical features or any combinations thereof that will be described below for illustrative purposes only. It is to be further understood that a plurality of features included in any one of the following modes of the invention are not necessarily provided altogether, and that the invention may be embodied without at least one of the features described with respect to the same mode.

(1) An apparatus for supplying, in an electric-component mounting system, a plurality of electric components to be mounted on a circuit substrate supported by a circuit-substrate supporting device, the apparatus comprising at least one support member; and a plurality of palettes each one of which is detachably attachable to the at least one support member and holds a plurality of feeders arranged in a reference direction predetermined with respect to the electric-component mounting system, each one of the feeders feeding a plurality of electric components of one sort, the palettes having different dimensions in the reference direction.

The support member may be either one which is undetachably (or permanently) attached to a base member of the electric-component supplying apparatus, or one which is detachably attached to the base member. In the latter case, it is preferred that it be easier to detach each palette from the support member than to detach the support member from the base member. Here, it is noted that the technical feature that the support member is undetachably attached to the base member means not only that the support member is literally undetachable from the base member, because of, e.g., welding, but also that the support member is fixed to the base member with, e.g., a number of bolts, i.e., that the support member can be detached from the base member if a long time is used, but the long time cannot be used during daily use of the electric-component mounting system. It is further noted that in the case where all the feeders held by each palette have a same width (i.e., a same dimension in the reference direction), a palette having a greater width can hold a greater number of feeders than a palette having a smaller width; but in the case where the feeders held by each palette have different widths, it cannot be always said that the former palette can hold a greater number of feeders than the latter palette, that is, the former palette may be able to hold only the same, or a smaller, number of feeders than the latter palette.

Since each palette that holds the feeders can be attached to, and detached from, the support member, it is possible to attach and detach the feeders to and from the palette, at a place outside the electric-component mounting system. Therefore, it is possible to attach and detach the feeders to and from the palette, during the operation of the electric-component mounting system. If there arises a need to exchange the current feeders with different feeders, the palette holding the current feeders can be exchanged with a different palette holding the different feeders. Thus, the feeder-exchanging operation can be carried out in a short time, which leads to improving the efficiency of the electric-component mounting operation and the rate of operation of the expensive electric-component mounting system.

In addition, since the plurality of palettes having the different widths (i.e., the different dimensions in the reference direction) are prepared, it is possible to select an appropriate palette, depending upon the sorts of the electric components to be treated as a group, e.g., the sorts of the electric components to be mounted on a circuit substrate of a certain sort. This improves the latitude of holding the feeders in the electric-component mounting system. More specifically described, electric components of various sorts can be divided into electric components of respective sorts that are commonly mounted on circuit substrates of different sorts and are held by a first palette, and electric components of respective sorts that are specifically mounted on circuit substrates of a specific sort and are held by a second palette. In this case, when the current, specific sort of circuit substrates are changed to a different sort of circuit substrates, only the second palette is exchanged with a different palette holding feeders that supply the electric components of respective sorts to be specifically mounted on each of the circuit substrates of the different sort. Meanwhile, when the feeders held by the above-indicated first palette have supplied all the electric components and accordingly need to be exchanged with new feeders, only the first palette is exchanged with a different palette that has been prepared to hold the new feeders. In this case, it is possible use, in place of the palettes having the different widths, palettes all having a same width. However, if the palettes having the different widths are employed, it is possible to select a palette having a width suitable for a group of feeders that supply electric components to be commonly mounted on different sorts of circuit substrates, and a palette having a width suitable for a group of feeders that supply electric components to be specifically mounted on a specific sort of circuit substrates. This increases the degree of latitude of holding the feeders in the electric-component mounting system.

A plurality of palettes as a group can cooperate with each other to hold a plurality of feeders as a group that supply all the electric components that are needed to be mounted on a circuit substrate. In this case, it is possible to prepare a plurality of palettes all having a same width (preferably, a same small width), and change the number of the palettes used, so as to change the number of the feeders that can be held by the palette or palettes used. However, since the palettes having the different widths are used, it is possible to more freely change the number of the feeders that can be held by the palette or palettes used.

In an electric-component mounting system of a type in which the support member is immovable and a mounting head is movable to each of the immovable feeders so as to receive an electric component therefrom, different palettes can hold different groups of feeders, respectively, that can supply different groups of electric components, respectively. In this case, the different palettes can be attached to the support member and, when the current sort of circuit substrates are changed to a different sort of circuit substrates, the current palette can be changed to a different palette that is to newly supply electric components to the mounting head. In this case, since it is possible to select the plurality of palettes having the respective different widths suitable for the respective numbers of feeders of the plurality of groups, the support table having a limited width can support the greatest possible number of feeders.

Moreover, in an electric-component mounting system of a type in which the support member is movable in the reference direction in which the feeders are arranged, so as to sequentially position each of necessary feeders at a prescribed component supplying position, only a palette holding a group of feeders can be attached to the support member. In this case, since the smallest palette that can hold the group of feeders can be selected, the mass that is moved with the support member can be minimized, which leads to reducing the vibration or noise produced by the present electric-component supplying apparatus.

(2) An apparatus according to the mode (1), wherein the palettes having the different dimensions in the reference direction hold different numbers of feeders, respectively.

(3) An apparatus according to the mode (1) or (2), wherein the plurality of palettes comprise at least three palettes having respective different dimensions in the reference direction.

If a greater number of palettes having respective different widths (i.e., respective different dimensions in the reference direction) are employed, it is possible to increase the degree of latitude of selecting a width (i.e., a dimension in the reference direction) of a palette attaching area on the support member where the palette or palettes is or are attached.

(4) An apparatus according to any of the modes (1) to (3), wherein the palettes having the different dimensions in the reference direction cannot all be simultaneously attached to the support member.

In the present electric-component supplying apparatus, after the greatest possible number of palettes that can be simultaneously attached to the support member are actually attached to the support member, at least one palette that is not attached to the support member is left. That is, one or more appropriate palettes are selected and attached to the support member.

(5) An apparatus according to any of the modes (1) to (4), wherein the feeders comprise at least one of (a) a tape feeder which feeds a carrier tape carrying a plurality of electric components of one sort and (b) a bulk feeder which stores a plurality of electric components of one sort in bulk, arranges the components into an array, and feeds the components arranged in the array.

The tape feeder feeds the carrier tape having a number of pockets each of which accommodates an electric component, so as to position the electric components, one by one, at a component-supply portion of the feeder. The bulk feeder stores, in a component storing portion thereof, electric components in bulk, arranges the electric components into an array by using an appropriate means, and feeds the components arranged in the array, so as to position the components, one by one, at a component-supply portion of the feeder. A plurality of tape feeders or bulk feeders are held by a palette such that the respective component-supply portions of the feeders are arranged along a single line (this line is usually a straight line; but it may be a curved line such as an arcuate line).

(6) An apparatus according to any of the modes (1) to (5), further comprising

a base member;

a guiding device which is provided between the base member and the at least one support member and supports the at least one support member such that the at least one support member is movable in the reference direction; and

a support-member moving device which moves the at least one support member in the reference direction to a predetermined component supplying position and positions an arbitrary one of the feeders held by at least one of the palettes that is attached to the at least one support member, at the predetermined component supplying position.

(7) An apparatus according to any of the modes (1) to (6), comprising a plurality of support members which are arranged in the reference direction, wherein at least one first member of the support members is movable in a component supplying area and, when the first member is moved in the component supplying area, at least one second member of the support members is kept still without interfering with the first member being moved in the component supplying area.

In the present electric-component supplying apparatus, while the first support member is moved in the component supplying area to supply the electric components, the second support member can be kept still so that one or more palettes attached thereto may be detached therefrom and exchanged with one or more different palettes.

(8) A method of supplying, in an electric-component mounting system, a plurality of groups of electric components to be mounted on a plurality of circuit substrates, respectively, each one of which is supported by a circuit-substrate supporting device, the method comprising the steps of:

supplying a first group of electric components from a first group of feeders held by at least one first palette detachably attached to a first area of a support member, the first group of feeders being held by the at least one first palette such that the first feeders are arranged in a reference direction predetermined with respect to the electric-component mounting system, each one of the first feeders feeding a plurality of electric components of one sort, and

detachably attaching, in place of the at least one first palette, at least one second palette to a second area of the support member, and supplying a second group of electric components from a second group of feeders held by the at least one second palette, the second group of feeders being held by the at least one second palette such that the second feeders are arranged in the reference direction, each one of the second feeders feeding a plurality of electric components of one sort, the first and second areas of the support member having different dimensions in the reference direction.

In the present electric-component supplying method, the plurality of palettes employed may be either ones all of which have a same width (i.e., a same dimension in the reference direction), or ones which have respective different widths. In the former case, the pallets need to have a same width that assures that at least two palettes can be simultaneously attached to the single support member. On the other hand, in the latter case, each palette may have a width that does not allow, when the each palette is attached to the single support member, another palette to be simultaneously attached to the same support member. In the former case, for example, a first area of the single support member in which a single palette is attached, and a second area of the single support member in which two palettes are attached have different dimensions in the reference direction. In the latter case, a first area of the single support member in which a first palette having a first width is attached, and a second area of the single support member in which a second palette having a second width different from the first width is attached have different dimensions in the reference direction.

The present electric-component supplying method may be combined with one or more of the above-described modes (2) to (6) of the electric-component supplying apparatus.

(9) A method according to the mode (8), wherein at least one of (a) the step of supplying the first group of electric components and (b) the step of supplying the second group of electric components comprises attaching a plurality of palettes to the support member.

(10) A method according to the mode (8) or (9), wherein the plurality of palettes have at least one of (a) different dimensions in the reference direction and (b) different numbers of the feeders that can be held thereby.

(11) A method according to any of the modes (8) to (10), wherein a total number of the at least one first palette attached to the support member differs from a total number of the at least one second palette attached to the support member.

(12) A method of supplying, in an electronic-component mounting system, a plurality of groups of electric components to be mounted on a plurality of circuit substrates, respectively, each one of which is supported by a circuit-substrate supporting device, the method comprising the steps of:

supplying a first group of electric components from a first group of feeders held by a plurality of first palettes detachably attached to a support member, the first group of feeders being held by the first palettes such that the first feeders are arranged in a reference direction predetermined with respect to the electric-component mounting system, each one of the first feeders feeding a plurality of electric components of one sort,

exchanging at least one of the first palettes attached to the support member, with at least one second palette which holds a second group of feeders such that the second feeders are arranged in the reference direction, each one of the second feeders feeding a plurality of electric components of one sort, and supplying a second group of electric components from at least the second group of feeders held by the at least one second palette.

Usually, the second group of electric components are supplied from not only the second group of feeders held by the at least one second palette but also the first group of feeders held by the at least one first palette left on the support member. However, in special cases, the second group of electric components are supplied from only the second group of feeders held by the at least one second palette. One of those special cases is the case where there arises a need to carry out an operation to produce a small number of electric circuits each of which requires mounting of only a small number of sorts of electric components, during an operation to produce a great number of electric circuits each of which requires mounting of a great number of sorts of electric components.

The present, second electric-component supplying method may be combined with one or more of the above-described modes (2) to (6) of the electric-component supplying apparatus and the above-described modes (10) and (11) of the first electric-component supplying method.

### BRIEF DESCRIPTION OF THE DRAWINGS

FIG. 1 is a plan view of an electronic-component mounting system as an embodiment of the present invention;

FIG. 2 is a partly cross-sectioned, side elevation view of a component mounting device of the mounting system of FIG. 1;

FIG. 3 is a side elevation view of a feeder of the mounting system;

FIG. 4 is a plan view of a component carrier tape fed by the feeder of FIG. 3;

FIG. 5 is a partly cross-sectioned, side elevation view of a relevant portion of a component supplying device of the mounting system;

FIG. 6 is a plan view of a palette of the component supplying device of FIG. 5;

FIG. 7 is a cross-sectioned, side elevation view of a moving-off preventing device that prevents the palette from moving off a movable table of the component supplying device;

FIG. 8A is a schematic plan view showing a first example in which a palette is attached to the movable table;

FIG. 8B is a schematic plan view showing a second example in which a palette is attached to the movable table;

FIG. 8C is a schematic plan view showing a third example in which two palettes are attached to the movable table;

FIG. 8D is a schematic plan view showing a fourth example in which two palettes are attached to the movable table;

FIG. 9 is a side elevation view of another feeder as a second embodiment of feeder; and

FIG. 10 is a plan view of another electronic-component mounting system as a third embodiment of feeder.

### DETAILED DESCRIPTION OF THE PREFERRED EMBODIMENTS

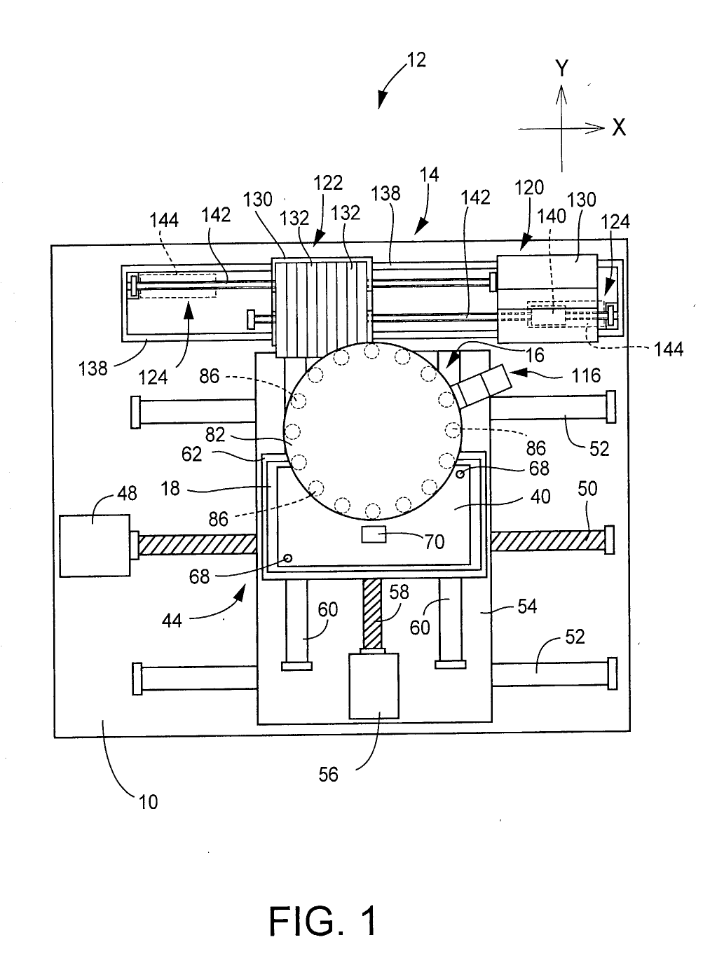

Hereinafter, there will be described in detail, by reference to the drawings, an embodiment of the present invention that is applied to an electronic-component mounting system 12 as a sort of electric-component mounting system. In FIG. 1, reference numeral 10 designates a base of the present electronic-component mounting system 12. On the base 10, there are provided a component supplying device 14, a component mounting device 16, and a printed-wiring-board supporting device 18 as a substrate supporting device all of which cooperate with each other to provide the mounting system 12.

The printed-wiring-board supporting device 18 supports a printed wiring board 40 as a sort of circuit substrate such that the printed wiring board 40 takes a horizontal posture. The supporting device 18 is moved, by an X-Y table 44 as a substrate-supporting-device moving device, to an arbitrary position on an X-Y coordinate plane. The X-Y table 44 includes an X-axis-slide drive motor 48, a ball screw 50 as a feed screw, a first guiding device including guide rails 52, an X-axis slide 54 that is moved in an X-axis direction by the motor 48 and the screw 50 while being guided by the first guiding device, a Y-axis-slide drive motor 56, a ball screw 58 as a feed screw, a second guiding device including guide rails 60, a Y-axis slide 62 that is moved, on the Y-axis slide 54, in a Y-axis direction by the motor 56 and the screw 58 while being guided by the second guiding device.

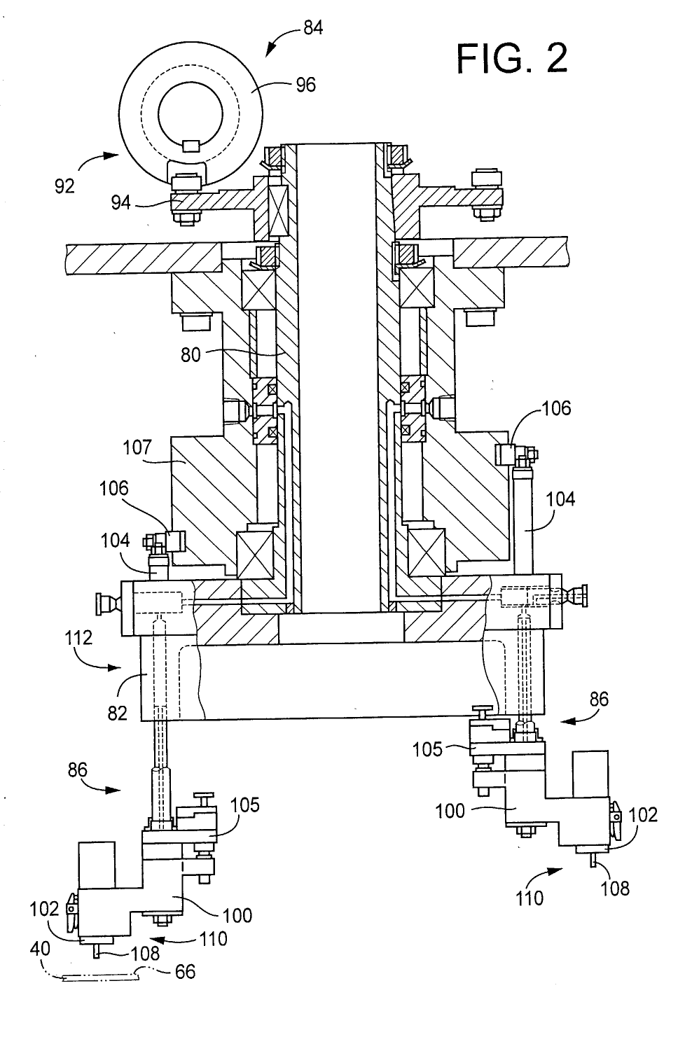

The printed-wiring-board supporting device 18 is provided on the Y-axis slide 62, and supports a lower surface of the printed wiring board 40 such that the printed wiring board 40 takes a horizontal posture. An upper surface 66 (FIG. 2) of the wiring board 40 has a plurality of prescribed component-mount places where respective electronic components are to be mounted. Owing to the movement of the printed-wiring-board supporting device 18, each of the prescribed component-mount places of the wiring board 40 is moved to, and positioned at, a position corresponding to a component mounting position of the component mounting device 16, described later.

The printed wiring board 40 has, on the upper surface 66, a plurality of (e.g., two) fiducial marks 68. Respective images of the two fiducial marks 68 of the wiring board 40 supported by the supporting device 18 are taken by a fiducial-mark camera 70 as an image taking device. The fiducial-mark camera 70 is supported by a support member, not shown, fixed to a main frame of the component mounting device 16, such that the camera 70 is fixed and oriented downward. Thus, the camera 70 takes the images of the fiducial marks 68 from a position above the wiring board 40.

The component mounting device 16 is basically identical with an electronic-component mounting device recited in Japanese patent document No. 7-36480 or its corresponding U.S. Pat. No. 4,747,198, and accordingly only pertinent elements of the mounting device 16 will be described by reference to FIG. 2. The mounting device 10 includes a main frame, not shown, a rotary shaft 80 that is supported by the main frame such that the rotary shaft 80 is rotatable about an axis line, for example, a vertical axis line, an intermittently rotatable body 82 as a rotatable member that is fixed to a lower end portion of the rotary shaft 80, an intermittently rotating device 84 that intermittently rotates the intermittently rotatable body 82, and a plurality of (e.g., sixteen) component mounting units 86 that are supported by the rotatable body 82.

The intermittently rotating device 84 includes an intermittently rotating motor, not shown, as a drive source, and a rotation transmitting device 92. The rotation transmitting device 92 includes a roller gear 94 and a roller cam, and converts the rotation of the intermittently rotating motor into intermittent rotations that are transmitted to the rotary shaft 80. Thus, the intermittently rotatable body 82 is intermittently rotated.

The sixteen component mounting units 86 are supported by the rotatable body 82 such that the mounting units 86 are located on a circle whose center rides on an axis line of rotation of the rotatable body 82 and are equiangularly spaced from each other about the axis line. Thus, the mounting device 16 concurrently receives an electronic component from the component supplying device 14 and mount another electronic component on the printed wiring board 40. Each of the sixteen component mounting units 16 includes a nozzle holder 100 and a plurality of (e.g., three) sorts of suction nozzles 102 that are held by the nozzle holder 100.

A rod 104 and a connecting member 105 cooperate with each other to attach the nozzle holder 100 to the rotatable body 82, such that the nozzle holder 100 is movable up and down in directions parallel to the axis line of rotation of the rotatable body 82. Since a cam follower 106 connected to the nozzle holder 100 is engaged with a cylindrical cam 107, the nozzle holder 100 is moved up and down as the rotatable body 82 is rotated. The nozzle holder 100 is rotatable, relative to the connecting member 105, about an axis line parallel to the axis line of rotation of the rotatable body 82 and, owing to the rotation of the nozzle holder 100, an appropriate one of the suction nozzles 102 is selected and positioned at an operative position. The operative suction nozzle 102 positioned at the operative position is supplied with a negative pressure, and a suction pipe 108 thereof sucks and holds an electronic component. In the present embodiment, the operative suction nozzle 102 positioned at the operative position and a portion of the nozzle holder 100 that holds the operative suction nozzle 102 cooperate with each other to provide a component holding device 110. However, it can be said that the portion of the nozzle holder 100 that holds the operative suction nozzle 102 provides a component holding device, or that each of the suction nozzles 102 provides a component holding device. In the last case, it can be said that the present system has forty-eight component holding devices in total, and each of the component mounting units 86 has three component holding devices in total.

The sixteen component holding devices 110 including the operative suction nozzle 102 positioned at the operative position, are revolved about a common axis line, i.e., the axis line of rotation of the rotatable body 82, as the rotatable body 82 is intermittently rotated, so that each of the holding devices 110 is stopped at each of sixteen stop positions on a locus of revolution thereof. In the present embodiment, the rotatable body 82 and the rotating device 84 cooperate with each other to provide a component-holding-device revolving device 112.

The above-described sixteen stop positions include a component receiving (sucking or holding) position corresponding to the component supplying device 14; a component-posture detecting position; a component-posture correcting position; a component mounting position corresponding to the printed-wiring-board supporting device 16; and a nozzle selecting position.

At each of the component receiving position and the component mounting position, a lowering device, not shown, is provided. The suction nozzles 102 are biased upward by respective springs, not shown, each functioning as a biasing device, and the operative suction nozzle 102 positioned at the operative position is lowered by each of the lowering devices against the biasing force of the spring, so that the operative nozzle 102 receives or mounts an electronic component. When the operative suction nozzle 102 sucks and holds an electronic component, a switch-valve device, not shown, is switched and the suction pipe 108 of the nozzle 102 is communicated with a negative-pressure source, not shown; and when the operative nozzle 102 mounts the electronic component, the switch-valve device is switched again so that the suction pipe 108 is communicated with atmosphere or a positive-pressure source, not shown, and is caused to release the electronic component.

At the component-posture detecting position, there is provided a component camera 116 as a sort of image taking device that functions as a component-posture detecting device. In the present embodiment, the component camera 116 is provided by a CCD (charge-coupled device) camera that functions as a surface-image taking device capable of taking, at once, a two-dimensional image of an object. The component camera 116 takes a silhouette image of the electronic component held by the suction nozzle 102. However, the component camera 116 may be replaced with a camera that takes an image of a front surface of the electronic component that faces the camera.

At the component-posture correcting position, there is provided a component-posture correcting device, not shown. The component-posture correcting device rotates the operative suction nozzle 102 positioned at the operative position, and thereby corrects an angular-position error of the electronic component held by the operative nozzle 102, about an axis line of the component. At the nozzle selecting position, there is provided a nozzle selecting device, not shown, that rotates the nozzle holder 100 and thereby selects an appropriate one of the three suction nozzles 102 and positions the selected nozzle 102 at the operative position.

Next, the component supplying device 14 will be described. As shown in FIG. 1, the component supplying device 14 includes a first component-supply table 120, a second component-supply table 120, and a component-supply-table moving device 124 that moves each of the two tables 120, 122.

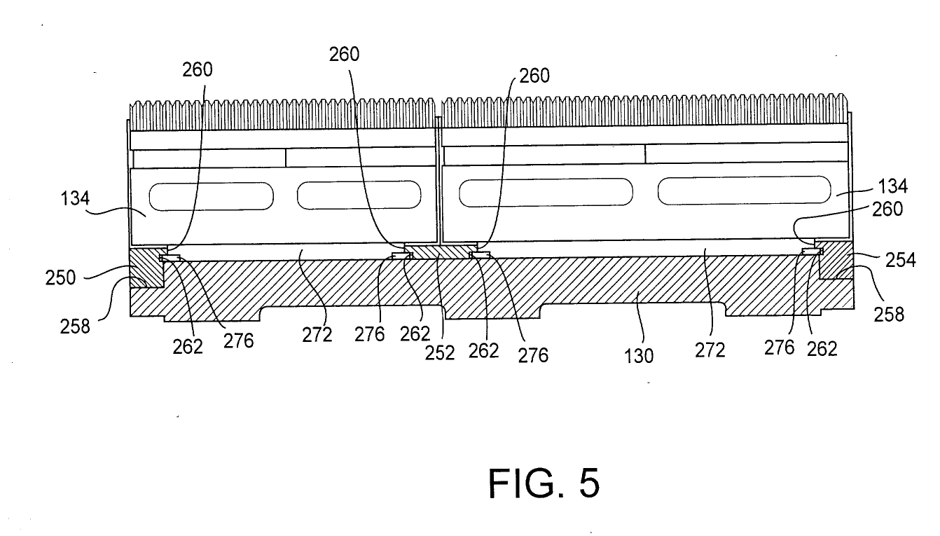

Each of the component-supply tables 120, 122 includes a movable table 130 as a sort of support table, and a palette 134 (FIG. 5) holding a plurality of feeders 132 is detachably attached to the movable table 130. Each of the feeders 132 is detachably attached to the palette 134 such that respective component-supply portions of the feeders 132 are arranged along a reference line, e.g., a straight line parallel to the X-axis direction (i.e., leftward and rightward directions in FIG. 1). The feeders 132, the palette 134, and the movable table 130 cooperate with one another to provide each component-supply table 120, 122. The palette 134 will be described in detail, later.

The movable table 130 of each of the first and second component-supply tables 120, 122 is supported by guide rails 138 extending parallel to the X-axis direction, such that the table 130 is movable in the X-axis direction. Each of the two movable tables 130 is guided by the guide rails 138, such that the component-supply portion of each of the feeders 132 mounted thereon is moved along the straight line along which the respective component-supply portions of the feeders 132 are arranged. The guide rails 138 are commonly used for both the first and second component-supply tables 120, 122, and the straight line along which the respective component-supply portions of the feeders 132 mounted on the first table 120 are arranged and the straight line for the second table 120 are located on a common straight line.

Two nuts 140 are fixed to the two movable tables 130, respectively, and are threadedly engaged with respective ball screws142 each as a sort of feed screw. The ball screws 142 are supported by the base 10, such that each of the ball screws 142 is rotatable about an axis line parallel to the X-axis direction and is immovable in the X-axis direction, and are rotated by respective exclusive table-drive motors 144 each as a drive source. Thus, the respective tables 130 of the first and second component-supply tables 120, 122 can be moved, independent of each other, in the direction in which the feeders 132 are arranged (i.e., the X-axis direction). The nuts 140, the ball screws 142, and the table-drive motors 144 cooperate with one another to provide the component-supply-table moving device 124. In FIG. 1, the feeders 132 mounted on the first component-supply table 120 are not shown to show the nut 140 fixed to the movable table 130 of the first table 120; and the nut 140 fixed to the movable table 130 of the second table 122 is not shown to show the feeders 132 mounted on the second table 122. The first and second component-supply tables 120, 122 have a common component supplying position where each of the two tables 120, 122 supplies electronic components to the component mounting device 16, and respective exclusive retracted positions that are located on opposite sides of the common component supplying position and at each of which a corresponding one of the two tables 120, 122 is positioned, when the other table is positioned at the component supplying position, such that the one table does not interfere with the other table.

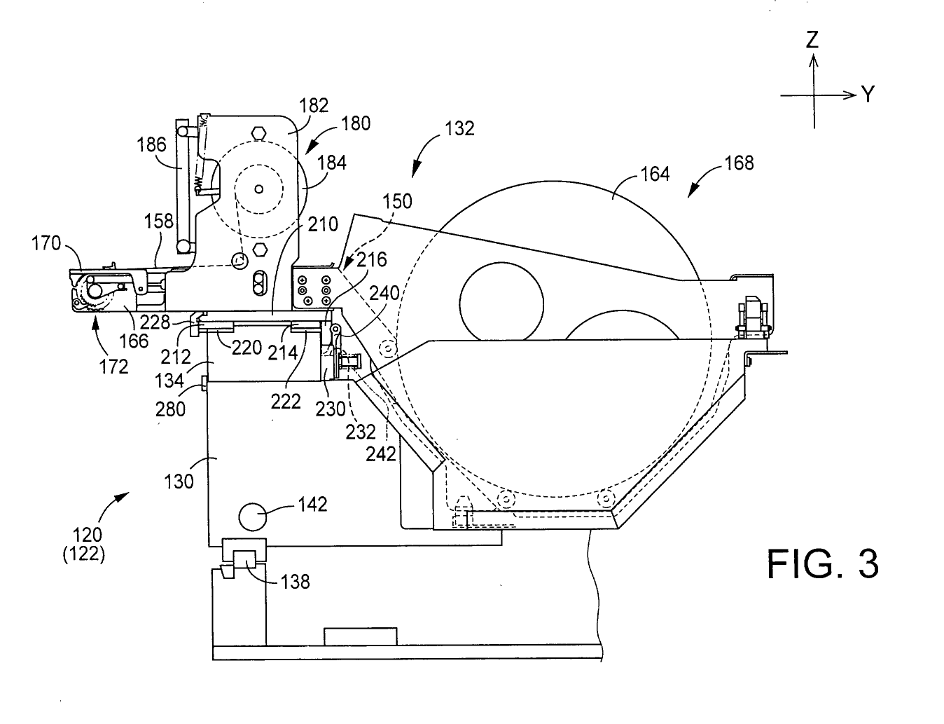

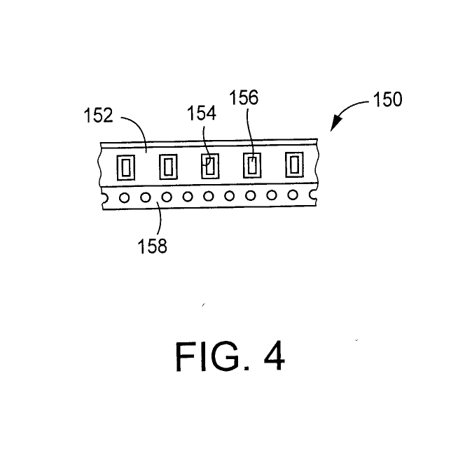

In the present embodiment, the electronic components supplied by each of the feeders 132 are provided in the form of a component carrier tape 150. As shown in FIG. 4, the component carrier tape 150 includes a component accommodating tape 152 having, at regular intervals of distance, component accommodating pockets 154 each of which accommodates an electronic component 156; and a cover tape 158 covering the component accommodating pockets 154. As shown in FIG. 3, the component carrier tape 150 is wound around a supply reel 164, which is held by a reel holder 168 as a sort of electronic-component storing device that is fixed to a rear end portion of a main frame 166 of the feeder 132 (i.e., an end portion of the frame 166 that is remote from the component mounting device 16). However, since the reel holder 168 is not relevant to the present invention, the reel holder 168 is not described any more here.

The main frame 166 of the feeder 132 has a generally elongate, plate-like configuration, and is attached to the component-supply table 120 or 122 such that the main frame 166 takes an upright posture in which both lengthwise and thicknesswise directions of the main frame 166 are horizontal. A certain length of the component carrier tape 150 is placed on an upper surface of the main frame 166, is covered by a cover 170, and is fed, by a feeding device 172, at a prescribed feeding pitch in the Y-axis direction perpendicular to the X-axis direction parallel to the lengthwise direction of the main frame 166. As far as the present application is concerned, the lengthwise direction of the main frame 166 will be referred to, when appropriate, as the front-and-rear direction of the feeder 132, and the thicknesswise direction of the main frame 166 will be referred to as the left-and-right or widthwise direction of the feeder 132. The front-and-rear direction of the feeder 132 is a direction in which the component carrier tape 150 is fed. The feeding device 172 is not described in detail since it is not relevant to the present invention. It is, however, noted that the feeding device 172 feeds forward the carrier tape 150 together with the cover 170 and, when the cover 170 is moved back, does not move the tape 150 back and prepares for the next one-pitch feeding of the tape 170.

The main frame 166 of the feeder 132 supports a cover-tape taking-up device 180 via a bracket 182. The cover-tape taking-up device 180 includes a take-up reel 184 that is not rotated, i.e., does not take up the cover tape 158, when the carrier tape 150 is fed forward. When the feeding device 170 prepared for the next one-pitch feeding of the tape 150, the take-up reel 184 is rotated to take up a certain length of the cove tape 158.

The feeding device 172 and the cover-tape taking-up device 180 are driven by a driving device including the intermittently rotating motor (not shown) as a drive source. The rotation of the intermittently rotating motor is converted, by a motion converting mechanism, not shown, including a cam, a cam follower, etc., into upward and downward movements of an elevator member (not shown). When the elevator member is moved up and down, an input bar 186 supported by the bracket 182 is moved up and down, so that the feeding device 172 and the cover taking-up device 180 are operated. Since the feeding of the component carrier tape 150 and the taking up of the cover tape 158 are not relevant to the present invention, those operations are not described in detail here.

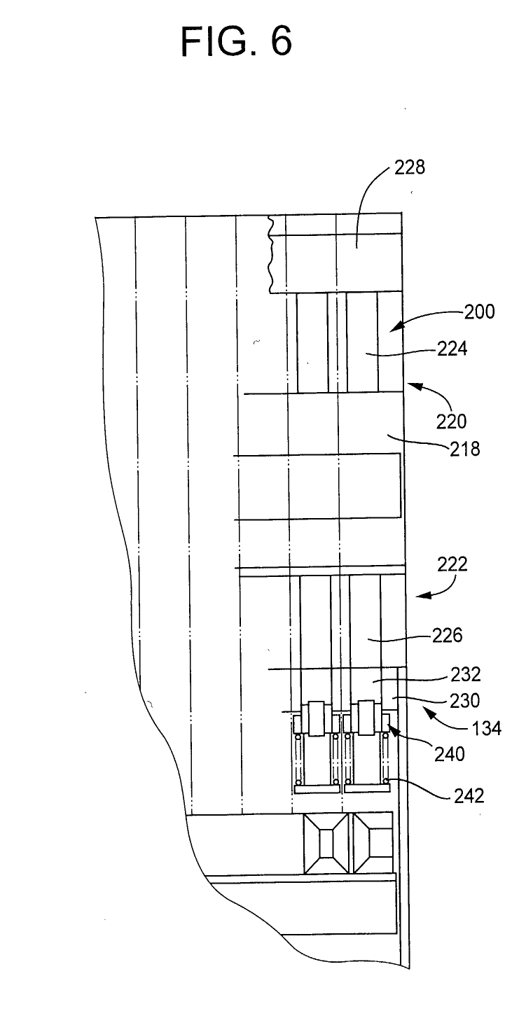

Next, there will be described a feeder attaching device that is for attaching the feeder 132 to the palette 134. As shown in FIG. 6, the palette 134 has a plurality of grooves or slots 200 formed at regular intervals of distance, and a feeder 132 is detachably attached to each one of the slots 200. In the present embodiment, as shown in FIG. 5, two palettes 134 can be simultaneously attached to the movable table 130 of the first component-supply table 120. One of the two palettes 134 has thirty slots 200, and the other palette 134 has forty slots 200. That is, the two palettes 134 has different widths, i.e., different dimensions in the direction in which the feeders 132 are arranged. Since, however, the two palettes 134 are otherwise similar to each other, one of the two pallets 134 will be described in detail below as a representative thereof.

In the present embodiment, two palettes 134 are attached to each one of the first and second component-supply tables 120, 122, and common sorts of feeders 132 are mounted on the two palettes 134 attached to the first table 120 and the two palettes 134 attached to the second table 122. One of the two palettes 134 attached to each of the two tables 120, 122 mainly supports such feeders 132 which supply electronic components commonly to a plurality of sorts of printed wiring boards 40, and the other palette 134 mainly supports such feeders 132 which supply electronic components exclusively to a particular sort of printed wiring boards 40.

As shown in FIG. 3, a plate-like, attaching member 210 having a width equal to a width of the main frame 166, is fixed with a bolt to a lower surface of the main frame 166. The main frame 166 is formed of an aluminum alloy so as to have a reduced weight. Meanwhile, the attaching member 210 is formed of carbon steel S50C and is hardened by quenching. The attaching member 210 supports two first positioning projections 212, 214 at respective locations distant from each other in the front-and-rear direction of the feeder 132. Each of the two first positioning projections 122, 124 has a rectangular cross section, has a width smaller than a width of the attaching member 210, and projects from a widthwise middle portion of the attaching member 210.

The attaching member 210 has, in a front end portion thereof, an inclined surface that is so inclined as to face upward and forward. In addition, the attaching member 210 has, in a rear end portion thereof, supports a plate-like, second positioning projection 216 having a width equal to the width of the first positioning projections 212, 214. The second positioning projection 216 projects vertically downward, i.e., perpendicularly from the attaching member 210 in a direction opposite to the main frame 166. The second positioning projection 216 has, in an intermediate portion thereof in the direction of projection thereof, a part-cylindrical, engaging surface that opens in a rear surface thereof and has a centerline parallel to the widthwise direction of the feeder 132. In addition, the second positioning projection 216 has, in the rear surface of a lower end portion thereof, an inclined, guiding surface that is so inclined as to face downward and rearward.

The palette 134 includes a base plate 218 formed of an aluminum alloy. Two first feeder-positioning plates 220, 222 are fixed to front and rear portions of an upper surface of the base plate 218, respectively, such that the first feeder-positioning plates 220, 222 extend in the X-axis direction. Like the attaching member 210, the first feeder-positioning plates 220, 222 are formed of carbon steel S50C and are hardened by quenching. As shown in FIG. 6, one first feeder-positioning plate 220 has, in an upper surface thereof, first positioning grooves 224 each extending in the Y-axis direction; and the other first feeder-positioning plate 222 has, in an upper surface thereof, first positioning grooves 226 each extending in the Y-axis direction. The grooves 224 or 226 are formed at the same pitch as the pitch at which the feeders 132 are attached. The first positioning grooves 224, 226 have a width very slightly greater than that of the first positioning projections 212, 214, and has a depth greater than a length of projection of the first positioning projecting portions 212, 214. The respective upper surfaces of the first feeder-positioning plates 220, 222 cooperate with each other to provide a support surface that supports the feeders 132.

A stopper plate 228 formed of carbon steel S50C and hardened by quenching is fixed to an upper end portion of a front surface of the base plate 218 of the palette 134. The stopper plate 228 has a plate-like configuration having a length substantially equal to a length of the base plate 218 in the X-axis direction, and an upper end portion of the plate 228 is located above the respective upper surfaces of the first feeder-positioning plates 220, 222. The upper end portion of the plate 228 includes a projecting portion projecting over the respective attaching members 210 of the feeders 132 and having an inclined, lower surface that is so inclined as to face downward and rearward and be able to engage the respective inclined surfaces of the attaching members 210.

A second feeder-positioning plate 230 different from the first feeder-positioning plates 220, 222 is fixed to a lower portion of a rear surface of the base plate 218 that is lower than the upper surface of the plate 218. The second feeder-positioning plate 230 is also formed of carbon steel S50C and has, in an upper surface thereof, a plurality of second positioning grooves 232 at the same pitch as the pitch at which the feeders 132 are attached. The second positioning grooves 232 have a width slightly greater than a width of the second positioning projection 216. The first and second positioning grooves 224, 226, 232 cooperate with one another to provide the slots 200 to which the feeders 132 are detachably attached.

Respective engaging members 240 are provided in rear of the respective slots 200 arranged as described above. The engaging members 240 are provided along a rear surface of the second positioning plate 230, and include respective engaging portions that can engage the respective engaging surfaces of the respective second positioning projections 216 of the feeders 132. The second feeder-positioning plate 230 is provided with compression coil springs, each as an elastic member, that bias the respective engaging portions of the engaging members 240 in a direction toward the base plate 218. Therefore, when a feeder 132 is attached to one slot 200, a corresponding engaging member 240 allows the second positioning projection 216 of the feeder 132 to enter a space between the engaging member 240 and the palette 134, against the biasing force of a corresponding spring 242; and, when the engaging surface of the second positioning projection 216 faces the engaging portion of the engaging member 240, the engaging surface is engaged with the engaging portion because of the biasing force of the spring 242. Thus, the feeder 132 is attached to the palette 134.

Next, there will be described a palette attaching device that is for attaching the palette 134 to the movable table 130. As shown in FIG. 5, the movable table 130 has a plurality of (e.g., three) guide members 250, 252, 254 provided thereon. The guide members 250, 252, 254 include two one-side guides 250, 254 that are provided in widthwise opposite end portions of the movable table 130; and one two-side guide 252 that is provided between the two one-side guides 250, 254, more specifically, in a boundary area between respective palette-attaching areas where the first and second palettes 134 are attached.

The three guide members 250, 252, 254 extend in the Y-axis direction parallel to respective lengthwise directions of the feeders 132. The movable table 130 has, at each of opposite end portions thereof, a recess 258 that extends in the Y-axis direction and opens in upper and side surfaces of the table 130. The two one-side guides 250, 254 are provided in the two recesses 258, respectively. Each of the recesses 258 has a depth that receives a corresponding one of the one-side guides 250, 254 such that an upper end portion of the one guide projects upward from the upper surface of the table 130. The one-side guides 250, 254 are fixed with bolts, not shown, to the table 130. The two-side guide 252 located in the boundary area between the two palette-attaching areas is detachably attached, with a plurality of bolts, not shown, to the upper surface of the table 130. To this end, the table 130 has, along the boundary area, a plurality of threaded holes that open in the upper surface and are threadedly engageable with the bolts to fix the two-side guide 252. The table 130 has additional threaded holes in the other areas than the boundary area. Thus, the two-side guide 252 can be attached to different positions on the table 130, and accordingly different sorts of palettes 134 having different widths can be attached to the table 130.

The two one-side guides 250, 254 have respective guide surfaces 260, and the two-side guide 252 has two guide surfaces 260. Therefore, the guide surface 260 of one 250 of the two one-side guides 250, 254 cooperates with one of the two guide surfaces 260 of the two-side guide 252 to guide one of the two palettes 134; and the guide surface 260 of the other one-side guide 254 cooperates with the other guide surface 260 of the two-side guide 252 to guide the other palette 134. The four guide surfaces 260 have respective engaging grooves 262. Respective lower surfaces of the respective engaging grooves 262 of the two one-side guides 250, 254 are flush with the upper surface of the movable table 130; and respective lower surfaces of the two engaging grooves 262 of the two-side guide 252 are defined by the upper surface of the movable table 130. The two palettes 134 are held by the three guide members 250, 252, 254, with substantially no clearances left. Thus, the palettes 134 are positioned relative to the movable table 130 in the X-axis direction, and the respective movements of the palettes 134 in the Y-axis direction are guided by the guide members 250, 252, 254.

The two palettes 134 includes respective fitting portions 272 fixed to respective lower surfaces of the respective base plates 218 thereof. The fitting portion 272 of one of the two palettes 134 that has the greater number of slots (e.g., forty slots) 200 than the other palette 134 having the smaller number of slots (e.g., thirty slots) 200, has a greater width than that of the other palette 134. The width of the fitting portion 272 of each of the palettes 134 is smaller than the width of the base plate 218 of the each palette 134. Thus, the fitting portion 272 of each of the two palettes 134 can fit, with substantially no clearances left, in the corresponding two guide surfaces 260 that are opposed to each other. The fitting portions 272 are higher than the guide members 250, 252, 254, so that in the state in which the palettes 134 are attached to the movable table 130 and respective lower surfaces of the fitting portions 272 are held in contact with the upper surface of the table 130, the guide members 250, 252, 254 are prevented from interfering with the respective base plates 218 of the palettes 134. Each of the fitting portions 272 has two engaging projections 276 that project from opposite side surfaces thereof and fit in the corresponding two engaging grooves 262. In the present embodiment, the engaging projections 276 are formed of a material that has more excellent mechanical properties, e.g., wear resistance, hardness, etc., than those of the material of which the respective remaining portions of the fitting portions 272 are formed. The engaging projections 276 are fixed to the remaining portions of the fitting portions 272, and function as part of the fitting portions 272. Each of the engaging projections 276 has a thickness that assures that the each engaging projection 276 fits in the corresponding engaging groove 262 with substantially no clearances left and is slideable relative to the groove 262. Thus, the palettes 134 are prevented from moving up off the movable table 130.

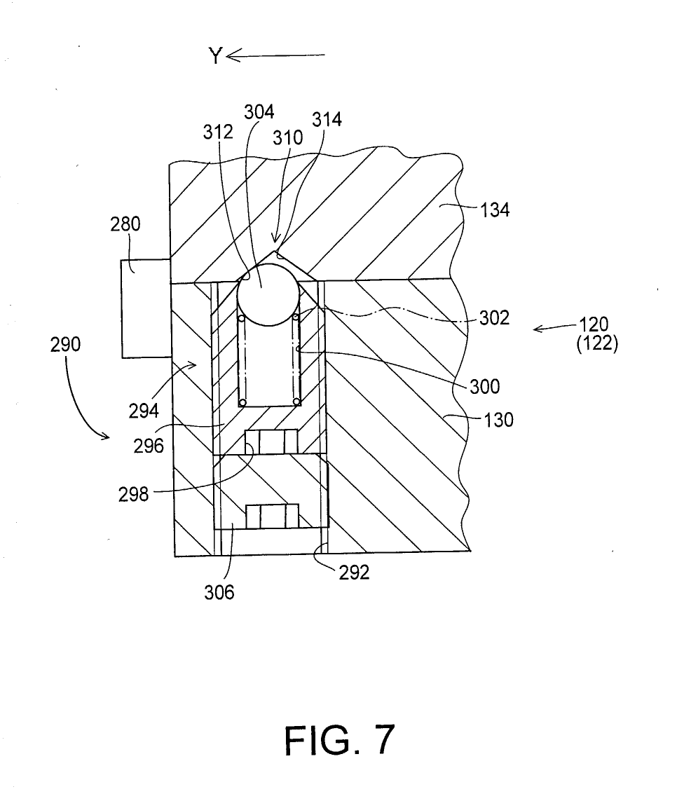

Each of the palettes 134 is attached to the movable table 130 in such a manner that first the engaging projections 276 of the each palette 134 are engaged, at one of opposite ends of the movable table 130 in the Y-axis direction, with the engaging grooves 262 of the corresponding two guide members of -the three guide members 250, 252, 254, and then are moved, on the table 130 in the Y-axis direction, to an attaching position while being guided by the corresponding two guide surfaces 260. The other end of the movable table 130 in the Y-axis direction is provided with a stopper member 280, as shown in FIG. 7, so that any further movement of the each palette 134 in the Y-axis direction is inhibited by engagement of the each palette 134 with the stopper member 280. Also, as shown in FIG. 7, the movable table 130 is provided with a plurality of moving-off preventing devices 290 each of which prevents the corresponding palette 134 from moving away from the stopper member 280. The moving-off preventing devices 290 cooperate with the stopper member 280 to provide a positioning device that positions the palettes 134 at the respective attaching positions on the movable table 130. Hereinafter, one of the moving-off preventing devices 290 will be described in detail below.

The movable table 130 has a plurality of internally threaded holes 292 that are formed through a thickness thereof such that the threaded holes 292 are spaced from each other in the X-axis direction. A plurality of externally threaded engaging members 294 are threadedly engaged with the plurality of threaded holes 292, respectively. Each of the engaging members 294 includes a generally cylindrical main body 296 that includes, at a lower end portion thereof remote from the palette 134, an operable portion 298 that is operable by a tool, not shown, to be rotated thereby. The main body 296 has a holding hole 300 that opens in an upper end portion thereof facing the palette 134. A compression coil spring 302 as an elastic member is provided in the holding hole 300, and a steel ball 304 is provided on the coil spring 302. The steel ball 304 is biased by the spring 302 in a direction in which the ball 304 comes out of the hole 300. Since, however, the diameter of the holding hole 300 is reduced around the opening thereof, a portion of the steel ball 304 is allowed to project from the hole 300 but the ball 304 cannot entirely come out of the hole 300. In addition, an upper portion of the main body 296 is so formed as to have a part-conical shape whose diameter is gradually reduced in a direction toward an upper end thereof. After a position of the engaging member 294 constructed as described above is adjusted in a direction parallel to an axis line thereof such that only the steel ball 304 projects from the upper surface of the movable table 130, an externally threaded fixing member 306 is threadedly engaged with a portion of the threaded hole 292 that is located below the engaging member 294, to such an extent that the fixing member 306 contacts a lower end of the engaging member 294. Thus, the fixing member 306 prevents a free rotation of the engaging member 294.

Each of the palettes 134 has an engaging groove 310 at a position that faces the steel balls 304 in the state in which the palette 134 is in contact with the stopper member 280. The engaging groove 310 is defined by two inclined surfaces 312, 314 that are symmetrically inclined with respect to a vertical plane parallel to the X-axis direction. One 312 of the two inclined surfaces 312, 314 that is nearer to the stopper member 280 is inclined such that as the surface 312 approaches the movable table 130, the surface 312 approaches the stopper member 280. The inclined surface 312 engages the steel balls 304. In the state in which the palette 134 is in contact with the stopper member 280, the center of the engaging groove 310 is located at a position remoter from the stopper member 280 than the center of each of the engaging members 294. Therefore, the one inclined surface 312 engages the steel balls 304, but the other inclined surface 314 does not engage the balls 304. The engaging groove 310 has a length corresponding to a plurality of engaging members 294, and cooperates with those engaging members 294 to provide one of the moving-off preventing devices 290.

When each of the palettes 134 is moved on the movable table 130 in the Y-axis direction to a position above the engaging members 294, the steel balls 304 are pushed downward against the biasing forces of the coil springs 302, so that the front end portion of the palette 134 is allowed to move over the steel balls 304. When the palette 134 engages the stopper member 280 and the engaging groove 310 faces the engaging members 294, the steel balls 304 are biased by the biasing forces of the springs 302 to engage the engaging surface 312 of the engaging groove 310. Because of the effect of inclination of the engaging surface 312, the palette 134 is biased by the steel balls 304 toward the stopper member 280, so that the palette 134 is prevented from moving off the movable table 130. However, when the palette 134 is strongly drawn by an operator, the engaging surface 312 pushes the steel balls 304 downward, so that the palette 134 is allowed to be drawn from the table 130.

The present electronic-component mounting system is operated under control of a control device, not shown. The control device is essentially provided by a computer including a CPU (central processing unit), a ROM (read only memory), a RAM (random access memory), a bus for coupling those elements with one another. The bus is additionally coupled to an input-and-output interface that is connected via respective drive circuits to the above-described various drive motors. The drive motors are associated with respective encoders that detect respective rotations and transmit the detected rotations to the control device. The ROM of the computer stores various control programs including a main routine for controlling the electronic-component mounting operation.

The electronic-component mounting operation of the present electronic-component mounting system 12 is described in detail in Japanese Patent Application No. 2001-220967 filed by the Assignee of the present application, or its corresponding U.S. Patent Application assigned to the Assignee of the present application. Since, however, the mounting operation is not relevant to the present invention, no detailed description thereof is provided here.

When, during the electronic-component mounting operation, there arises a need to exchange the feeders 132 supported by the first or second component-supply table 120, 122, for example, when all the electronic components have been supplied, the movable table 130 supporting the feeders 132 is moved from the component supplying area to the corresponding retracted area. For example, if there arises a need to exchange the feeders 132 supported by the first component-supply table 120, the first table 120 is retracted to the retracted area,a nd the second table 122 is moved to the component supplying area to be ready for supplying electronic components 156 to the component mounting device 16.

The operator draws each of the palettes 134 supported by the first table 120, in the Y-axis direction, more specifically, in a direction away from the stopper member 280, and thereby remove the palettes 134 from the movable table 130. If the operator strongly draws each palette 134, the steel balls 304 of the moving-off preventing device 290 are pushed downward against the biasing forces of the springs 302, so that the palette 134 is allowed to be drawn. Then, the operator attaches, to the movable table 130, other palettes 134 each of which has been prepared to hold necessary feeders 132. The engaging projections 276 of the fitting portion 272 of each of the palettes 134 are engaged with the engaging grooves 262, and the each palette 134 is forcedly pushed along the corresponding two guide members of the three guide members 250, 252, 254, so that the steel balls 304 of the moving-off preventing device 290 are pushed downward and the palette 134 is allowed to be moved. When the front end portion of the palette 134 engages the stopper member 280, the engaging surface 312 is positioned at the position where the surface 312 faces the engaging members 294, so that the steel balls 304 project upward because of the biasing forces of the springs 302 and engage the engaging surface 312. Because of the effect of inclination of the engaging surface 312, the palette 134 is pushed against the stopper member 280, and accordingly is fixed to the movable table 130. Thus, one palette-detaching-and-attaching operation is finished.

According to the present invention, each palette 134 can be prepared, in advance, to hold necessary feeders 132, which contributes to improving the efficiency of the feeder exchanging operation. In addition, since a plurality of palettes 134 can be attached to a single movable table 130, the weight of each palette 134 can be reduced, which also contributes to improving the efficiency of the feeder exchanging operation. However, it is noted that when the feeders 132 are exchanged, it is not essentially needed to exchange the palettes 134. For example, in the case where only some of the feeders 132 held by a certain palette 134 are exchanged with new feeders, the same palette 134 is attached again. In addition, it is possible to detach and attach feeders 132 from and to a palette 134 in the state in which the palette 134 is attached to the movable table 130.

The illustrated mounting system 12 can be used to mount electronic components on each of printed wiring boards 40 of different sorts. In this case, some of the feeders 132 held by a “common” palette 134 that supplies electronic components commonly to the different sorts of boards 40 are likely to have supplied all electronic components and accordingly need to be exchanged. Therefore, only the common palette 134 can be exchanged with another common palette 134 that has been prepared, in advance, to hold feeders 132. On the other hand, a “special” palette 134 holds feeders 132 that supply electronic components to only a special sort of boards 40. The current special palette 134 can be exchanged with a different sort of special palette 134 holding different feeders 132, when the current sort of printed wiring boards 40 are changed to a different sort of boards 40.

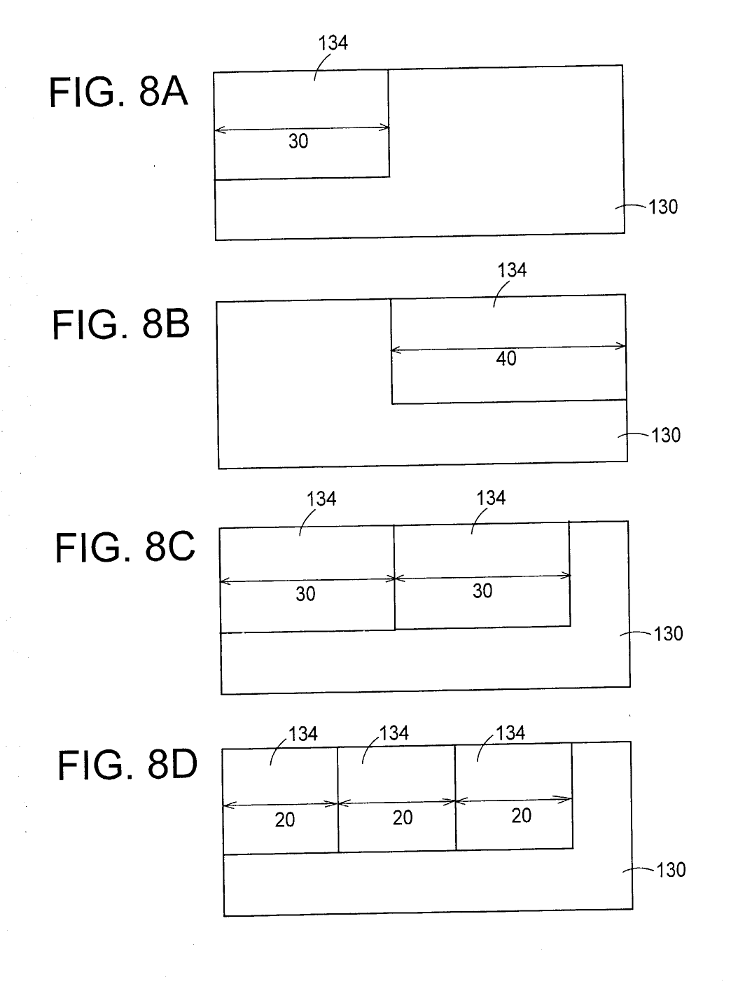

In the illustrated embodiment, the two palettes 134 having the different widths are detachably attached to each of the two movable tables 130. However, it is possible to attach only one of the two palettes 134 to each movable table 130. For example, in the case where the number of the sorts of electronic components to be mounted on the printed wiring board 40 is small, it is possible to attach, as shown in FIG. 8A, only one palette 134 having thirty slots 200 and holding necessary feeders 132, to a movable table 130. In the case where the number of the sorts of electronic components to be mounted on the printed wiring board 40 is greater than thirty and not greater than forty, it is possible to attach, as shown in FIG. 8B, only one palette 134 having forty slots 200 and holding necessary feeders 132, to a movable table 130. Moreover, in the case where the number of the sorts of electronic components to be mounted on the printed wiring board 40 is greater than forty, it is possible to attach, as described previously, the palette 134 having the thirty slots 200 and holding necessary feeders 132 and the palette 134 having the forty slots 200 and holding necessary feeders 132, to a movable table 130. In each case, the mass moved by each component-supply table 120, 122 can be minimized. Furthermore, it is possible to prepare more than four palettes 134 each having thirty slots 200 and attach, as shown in FIG. 8C, two palettes 134 to each of the two component-supply tables 120, 122. In the last case, it is possible to employ two two-side guides 252 and one of the two one-side guides 250, 254, or employ three two-side guides 252, so as to define, on each movable table 130, two palette-attaching areas where the two palettes 134 are to be attached.

Additionally, it is possible to attach three or more palettes 134 to each component-supply table 120, 122. More specifically described, a number of palettes 134 each having a considerably small width are prepared, and the number of the palettes 134 to be attached to each movable table 130 is changed depending upon the number of the sorts of electronic components to be mounted on a printed wiring board 40. For example, it is possible to prepare a number of palettes 134 each having twenty slots 200 and simultaneously attach, as shown in FIG. 8D, at most three palettes 134 to each movable table 130. In addition, it is possible to prepare a plurality of first palettes 134 each having twenty slots 200 and a plurality of second palettes 134 each having thirty slots 200, and attach an appropriate combination of at least one first palette 134 and at least one second palette 134, to each movable table 130, so as to maximize the number of the feeders to be supported by each movable table 130. In either case, it is preferred to employ an appropriate number of two-side guides 252 and locate those guides 252 at respective appropriate positions corresponding to the respective widths of the first and second palettes 134 to be attached.

In the illustrated embodiment, the position of the guide member (two-side guide) 252 on each movable table 130 can be changed, or the number of the guide members 252 employed can be changed, to change the position of the palette-attaching area or the number of the palette-attaching areas. However, it is possible to employ a feeder-support member that includes a movable table and a plurality of palette-hold members each detachably attachable to the movable table. In this case, the palette-hold members have different palette-attaching areas, respectively, and an appropriate one of the palette-hold members is selected depending upon the sort or sorts of the palette or palettes to be attached to the movable table. The selected palette-hold member is attached to the movable table, ant then the palette or palettes is or are attached to the palette-hold member. In this case, the position or positions of the two-side guide or guides 252 used with each palette-hold member may be either unchangeable or changeable.

In the case where a plurality of palettes 134 are attached to each component-supply table 120, 122, the palettes 134 may hold only the feeders 132 that supply the electronic components 156 to be mounted on the current sort of printed wiring boards 40. However, if it is known that, in near future, the current sort of the boards 40 is changed to a different sort of boards 40 and accordingly the current sorts of the electronic components 156 to be mounted are also changed, it is possible to additionally attach, to each movable table 130, a palette 134 holding feeders 132 that supply the sorts of electronic components 156 to be mounted on the next sort of boards 40.

In the case where, during a first operation in which a great number of sorts of electronic components 156 are mounted on each of a great number of printed wiring boards of a certain sort, there arises a need to carry out a second operation in which a small number of sorts of electronic components 156 are mounted on each of a small number of printed wiring boards of a different sort, it is possible to exchange only a portion (one, two, or more, but not all) of the palettes 134 currently attached to each movable table 130, with one, two, or more different palettes 134. In this case, after the second operation has been finished, it is possible to restore the initial arrangement of the palettes 134 to resume the first operation. Thus, the operator's operation needed to exchange the palettes 134 can be minimized.

In the illustrated embodiment, all the feeders 132 have a same width, and are attached to the palettes 134 having the slots 200 each having a same width. However, it is possible to employ feeders having different widths. In this case, though it is possible to prepare a special palette having slots having different widths corresponding to the different widths of the feeders, it is preferred to commonly use the same palettes 134 such that a feeder having a great width is attached to two or more slots 200.

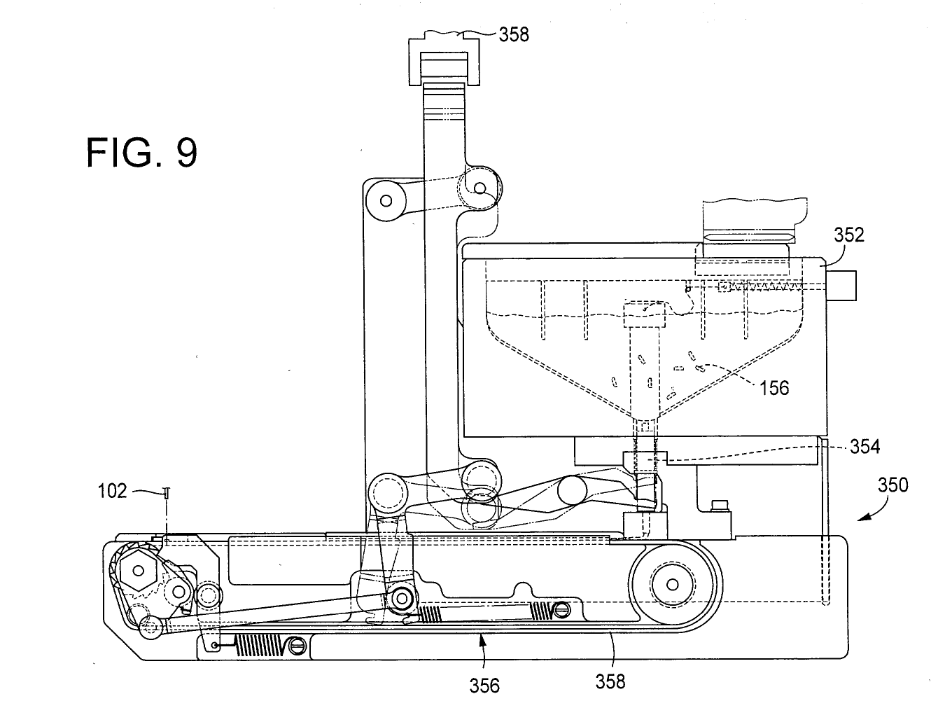

In the illustrated embodiment, each feeder 132 is a tape feeder that feeds the carrier tape 150 carrying the electronic components 156 and thereby supplies the components 156. However, the component supplying device 14 may employ different sorts of feeders. For example, the feeders 132 may be replaced with bulk feeders 350 one of which is shown in FIG. 9. The bulk feeder 350 stores electronic components 156 in bulk, arranges the components 156 into an array, and feeds and supplies the components 156 arranged in the array. Since the bulk feeder 350 is substantially identical with the bulk feeder disclosed in Japanese patent document No. 2000-244186 or its corresponding U.S. Pat. No. 6,332,558 assigned to the Assignee of the present application, only a brief description thereof is provided here. The bulk feeder 250 includes a case 352 having a storing chamber in which electronic components 156 are stored. The case 352 is provided with a discharge-promoting member 354 that is vertically movable. When the discharge-promoting member 354 is vertically moved, the discharging of the electronic components 156 from the storing chamber of the case 352 is promoted. In addition, the bulk feeder 350 includes a component conveying device 356 that conveys the electronic components 156 discharged from the case 252, to a component supplying position. More specifically described, the conveying device 356 includes a belt 358 on which the electronic components 156 discharged from the case 352 are arranged in an array and are conveyed to the component supplying position. The component conveying device 356 and the discharge-promoting member 354 are driven by an elevator member 358 that, in turn, is driven by the previously-described intermittently rotating motor, not shown.

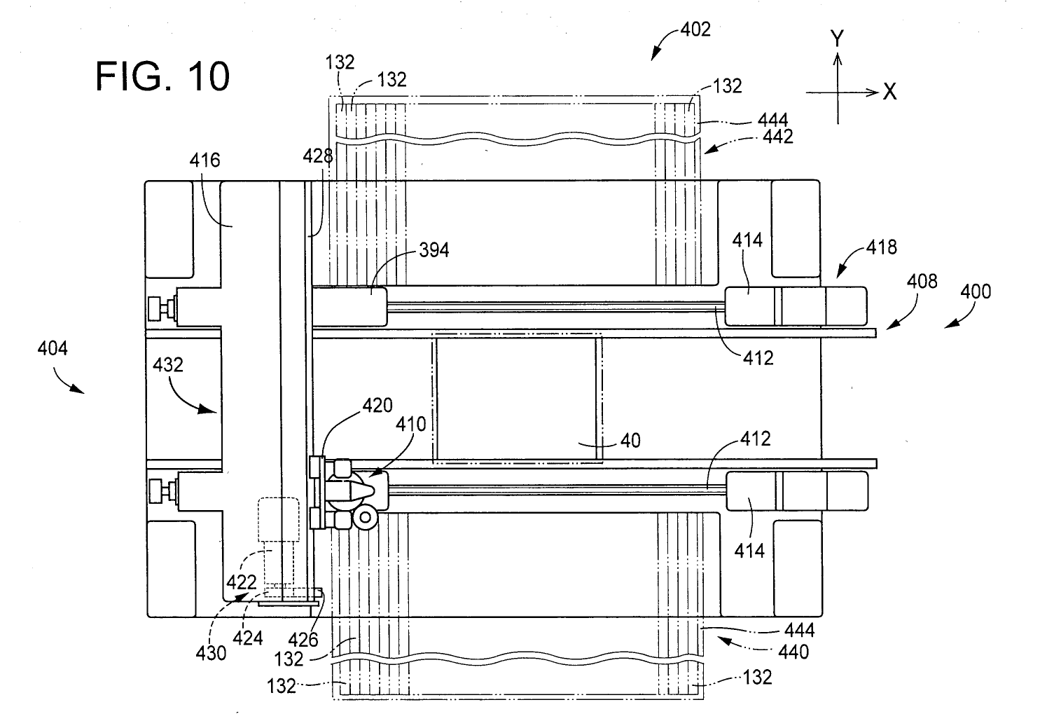

In the illustrated embodiment, the feeders 132 are supported by the movable tables 130 such that the feeders 132 are arranged in the X-axis direction and, owing to the movements of the movable tables 130, an arbitrary one of the feeders 132 is positioned at the component supplying position so as to supply the electronic components 156 to the component mounting device 16. However, the movable tables 130 may be replaced with one or more immovable support members. For example, as shown in FIG. 10, an “X-Y-table-type” electronic-component mounting system 400 employs an immovable component supplying device 402 including a plurality of feeders 132. Hereinafter, the present mounting system 400 will be described briefly.

The present mounting system 400 includes, in addition to the component supplying device 402, a component mounting device 404 that receives electronic components 156 from the component supplying device 402, and mounts the components 156 on a printed wiring board 40; and a wiring-board conveyor 408 that conveys the wiring board 40 in an X-axis direction.

In the present embodiment, the wiring-board conveyor 408 conveys the printed wiring board 40 in a state in which the wiring board 40 takes a horizontal posture, and a stopping device, not shown, stops the wiring board 40 at a prescribed component mounting position where the wiring board 40 is supported by a wiring-board supporting device, not shown. In the present embodiment, the printed wiring board 40 is supported in a state in which an upper surface (i.e., component-mount surface) of the board 40 on which the electronic components 156 are to be mounted takes a horizontal posture.

The component mounting device 404 includes a holding head that sucks and holds the electronic components 156 and is moved in a direction having respective components in an X-axis direction and a Y-axis direction perpendicular to each other so as to convey the electronic components 156 and mount the components 156 on the component-mount surface of the printed wiring board 40. To this end, as shown in FIG. 10, two ball screws 412 each as a feed screw are provided on both sides of the wiring-board conveyor 408 in the Y-axis direction, such that the two ball screws 412 extend parallel to each other in the X-axis direction. The two ball screws 412 are threaded engaged with two nuts, not shown, respectively, that are fixed to an X-axis slide 416. When the two ball screws 412 are rotated in synchronism with each other by two X-axis-slide move motors 414 each as a drive source, respectively, the X-axis slide 416 is moved to an arbitrary position in the X-axis direction. Thus, the nuts, the ball screws 412, the X-axis-slide move motors 414, etc. cooperate with one another to provide an X-axis-slide moving device 418.

The X-axis slide 416 supports a ball screw as a feed screw, not shown, such that the ball screw extends in the Y-axis direction and is threadedly engaged with a nut fixed to a Y-axis slide 420. When the ball screw is rotated by a Y-axis-slide move motor 422 as a drive source via gears 424, 426, the Y-axis slide 420 is moved to an arbitrary position in the Y-axis direction, while being guided by a pair of guide rails 428 (only one guide rail 428 is shown in FIG. 10). Thus, the nut, the ball screw, the Y-axis-slide move motor 422, etc. cooperate with one another to provide a Y-axis-slide moving device 430, which cooperates with the X-axis slide 416, the X-axis-slide moving device 418, and the Y-axis slide 420 to provide an X-Y robot 432 as a moving device. Thus, the X-Y robot 432 moves the holding head 410 to an arbitrary position on a horizontal plane.

The component supplying device 402 includes a first component-supply table 440 and a second component-supply table 442 that supply the electronic components 156 and are located on both sides of the wiring-board conveyor 408 in the Y-axis direction. Each of the first and second component-supply tables 440, 442 includes a stationary table 444 as an immovable support member, and a plurality of palettes 134 each holding a plurality of feeders 132 are detachably attached to each of the stationary tables 444. The feeders 132 are arranged, on each palette 134, along a straight line parallel to the X-axis direction.

In the present electronic-component mounting system 400, too, a plurality of palettes 134 can be attached to each of the stationary tables 444, and one or more palettes 134 holding the feeders 132 that supply the sorts of electronic components 156 to be mounted is or are selected from all the palettes 134 prepared, and are attached to each stationary table 444. Here, it is possible to attach, to each stationary table 444, only the palette or palettes 134 that is or are needed for the current electric-component mounting operation. However, if each stationary table 444 has a vacant space capable of supporting one or more additional palettes 134, it is possible to attach, in advance, one or more palettes 134 holding the feeders 132 that supply the electronic components 156 to be mounted on the next sort of printed wiring boards 40. In this case, the total number of the palette detaching and attaching operations can be reduced.

While the present invention has been described in detail in its embodiments, it is to be understood that the present invention is not limited to the details of those embodiments and may be embodied with various changes and improvements, such as those described in SUMMARY OF THE INVENTION, which may occur to a person skilled in the art.

What is claimed is:

1. An apparatus for supplying, in an electric-component mounting system, a plurality of electric components to be mounted on a circuit substrate supported by a circuit-substrate supporting device, the apparatus comprising:
at least one support member; and
a plurality of palettes each one of which is detachably attachable to said at least one support member and holds a plurality of feeders arranged in a reference direction predetermined with respect to the electric-component mounting system, each one of the feeders feeding a plurality of electric components of one sort, the palettes having different dimensions in the reference direction.

2. An apparatus according to claim 1, wherein the palettes having the different dimensions in the reference direction hold different numbers of feeders, respectively.

3. An apparatus according to claim 1, wherein the plurality of palettes comprise at least three palettes having respective different dimensions in the reference direction.

4. An apparatus according to claim 1, wherein the palettes having the different dimensions in the reference direction cannot all be simultaneously attached to the support member.

5. An apparatus according to claim 1, wherein the feeders comprise at least one of (a) a tape feeder which feeds a carrier tape carrying a plurality of electric components of one sort and (b) a bulk feeder which stores a plurality of electric components of one sort in bulk, arranges the components into an array, and feeds the components arranged in the array.

6. An apparatus according to claim 1, further comprising:
a base member;
a guiding device which is provided between the base member and said at least one support member and supports said at least one support member such that said at least one support member is movable in the reference direction; and
a support-member moving device which moves said at least one support member in the reference direction to a predetermined component supplying position and positions an arbitrary one of the feeders held by at least one of the palettes that is attached to said at least one support member, at the predetermined component supplying position.

7. An apparatus according to claim 1, comprising a plurality of support members which are arranged in the reference direction, wherein at least one first member of the support members is movable in a component supplying area and, when the first member is moved in the component supplying area, at least one second member of the support members is kept still without interfering with the first member being moved in the component supplying area.

8. A method of supplying, in an electric-component mounting system, a plurality of groups of electric components to be mounted on a plurality of circuit substrates, respectively, each one of which is supported by a circuit-substrate supporting device, the method comprising the steps of:
supplying a first group of electric components from a first group of feeders held by at least one first palette detachably attached to a first area of a support member, the first group of feeders being held by said at least one first palette such that the first feeders are arranged in a reference direction predetermined with respect to the electric-component mounting system, each one of the first feeders feeding a plurality of electric components of one sort, and
detachably attaching, in place of said at least one first palette, at least one second palette to a second area of the support member, and supplying a second group of electric components from a second group of feeders held by said at least one second palette, the second group of feeders being held by said at least one second palette such that the second feeders are arranged in the reference direction, each one of the second feeders feeding a plurality of electric components of one sort, the first and second areas of the support member having different dimensions in the reference direction.

9. A method according to claim 8, wherein at least one of (a) the step of supplying the first group of electric components and (b) the step of supplying the second group of electric components comprises attaching a plurality of palettes to the support member.

10. A method according to claim 9, wherein the plurality of palettes have at least one of (a) different dimensions in the reference direction and (b) different numbers of the feeders that can be held thereby.

11. A method according to claim 8, wherein a total number of said at least one first palette attached to the support member differs from a total number of said at least one second palette attached to the support member.

12. A method of supplying, in an electric-component mounting system, a plurality of groups of electric components to be mounted on a plurality of circuit substrates, respectively, each one of which is supported by a circuit-substrate supporting device, the method comprising the steps of:
supplying a first group of electric components from a first group of feeders held by a plurality of first palettes detachably attached to a support member, the first group of feeders being held by the first palettes such that the first feeders are arranged in a reference direction predetermined with respect to the electric-component mounting system, each one of the first feeders feeding a plurality of electric components of one sort,
exchanging at least one of the first palettes attached to the support member, with at least one second palette which holds a second group of feeders such that the second feeders are arranged in the reference direction, each one of the second feeders feeding a plurality of electric components of one sort, and
supplying a second group of electric components from at least the second group of feeders held by said at least one second palette.
